(19) United States
(12) Patent Application Publication
(10) Pub. No.: US 2006/0157757 A1
(43) Pub. Date: Jul. 20, 2006

(54) Image display device

(76) Inventors: Yoshiyuki Kaneko, Hachioji (JP); Yuuichi Kijima, Chosei (JP); Masakazu Sagawa, Inagi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/335,494

(22) Filed: Jan. 20, 2006

(30) Foreign Application Priority Data
Jan. 20, 2005 (JP) 2005-012341

(51) Int. Cl. H01L 31/113

(52) U.S. Cl. 257/291; 257/294; 257/E27.132; 257/72

(57) ABSTRACT

The present invention provides an image display device which can enhance the overlapping positional accuracy of both substrates and can exhibit a prolonged lifetime and a high quality display by suppressing the generation of sparks. A plurality of island-like electrodes are arranged on a back substrate, the island-like electrodes are held at a given potential, counter electrodes which correspond to the island-like electrodes are formed on a face substrate, and the counter electrodes are connected to an anode electrode.

### BACKGROUND OF THE INVENTION

1. Field of the Invention

The present invention relates to a planar image display device, and more particularly to an image display device which enhances an accuracy of overlapped position between a face substrate and a back substrate thereof.

2. Description of the Related Art

A color cathode ray tube has been popularly used conventionally as an excellent display device which exhibits high brightness and high definition. However, along with the realization of high image quality of recent information processing device and television broadcasting, there has been a strong demand for a planar image display device (flat panel display: FPD) which is light-weighted and requires a small space for installation while ensuring the excellent properties such as high brightness and high definition.

As typical examples of such a planar image display device, a liquid crystal display device, a plasma display device or the like has been put into practice. Further, particularly with respect to the planar display device which can realize the high brightness, with respect to a self luminous display device which makes use of emission of electrons into vacuum from electron sources, various planar image display devices such as an electron emission type image display device, a field emission type image display device, an organic EL display which is characterized by low power consumption and the like are expected to be put into practice in near future.

Among these planar image display devices, with respect to the self-luminous flat panel display, there has been known a display device having the constitution in which electron sources are arranged in a matrix array, wherein as one such display, there has been also known the above-mentioned electron emission type planer image display device (hereinafter, referred to as an electron emission type FPD) which makes use of minute and integrative cold cathodes.

Further, in the self-luminous flat panel display, as cold cathodes, thin film electron sources of a spindle type, a surface conduction type, a carbon nanotubes type, an MIM (Metal-Insulator-Metal) type which laminates a metal layer, an insulator and a metal layer, an MIS (Metal-Insulator-Semiconductor) type which laminates a metal layer, an insulator and a semiconductor layer, a metal-insulator-semiconductor layer-metal or the like has been used.

With respect to the MIM type electron source, for example, there has been known an electron source which is disclosed in Japanese Patent Laid-open Hei7(1995)-65710 (patent document 1) and Japanese Patent Laid-open Hei10(1998)-153979 (patent document 2), for example. Further, with respect to the metal-insulator-semiconductor electron source, there has been known an MOS type electron source reported in j. Vac. Sci. Technol. B11 (2) p. 429-432 (1993) (non-patent document 1). Further, with respect to the metal-insulator-semiconductor-metal type electron source, there has been known a HEED type electron source reported in high-efficiency-electro-emission device, Jpn. J. Appl. Phys., vol36, pL939 (non-patent document 2), an EL type electron source reported in Electroluminescence, Applied Physics, Volume 63, No. 6, p. 592 (non-patent document 3), or a porous silicon type electron source reported in Applied Physics, Volume 66, No. 5, p. 437 (non-patent document 4).

As the electron emission type FPD, there has been known a display panel which is constituted of a back substrate which includes the electron sources described above, a face substrate which includes phosphor layers and an anode to which an acceleration electrode for allowing electrons emitted from electron sources to impinge on the phosphor layers is applied, and a support body which allows the back substrate and the face substrate to face each other in an opposed manner and constitutes a sealing frame for sealing an inner space formed by opposing surfaces of both substrates into a given vacuum state. The electron emission type FPD is operated in a state that drive circuits are combined with the display panel.

The image display device having the MIM type electron sources includes aback substrate, wherein on the back substrate, a large number of first electrodes (for example, cathode electrodes, video signal electrodes) which extend in the first direction and are arranged in parallel in the second direction which intersects the first direction, an insulation film which is formed in a state that the insulation film covers the first electrodes, a large number of second electrodes (for example, gate electrodes, scanning signal electrodes) which extend in the second direction and are arranged in parallel in the first direction over the insulation film, and electron sources which are provided in the vicinity of intersecting portions of the first electrodes and second electrodes are formed. The back substrate includes a substrate made of an insulation material and the above-mentioned electrodes are formed on the substrate.

In such a constitution, a scanning signal is sequentially applied to the scanning signal electrodes in the first direction. Further, on the substrate, the above-mentioned electron source is provided in the vicinity of each intersecting portion of the scanning signal electrode and the image scanning electrode, both electrodes and the electron source are connected with each other using a power supply electrode so that an electric current is supplied to the electron source.

A face substrate is arranged to face the back substrate in an opposed manner, wherein phosphor layers of plural colors and a third electrode (anode electrode, anode) are formed on an inner surface of the face substrate which faces the back substrate in an opposed manner.

The face substrate is made of a light-transmitting material which is preferably glass. Further, both substrates are sealed by inserting a support body which constitutes a sealing frame between laminating inner peripheries of both substrates, and the inside which is formed by the back substrate, the face substrate and the support body is evacuated thus constituting a display panel.

The electron sources are provided in the vicinity of the intersecting portion of the first electrode and the second electrode as mentioned above and an emission quantity of electrons from the electron source is controlled based on a potential difference between the first electrode and the second electrode (including the turning on and off of the emission). The emitted electrons are accelerated due to a high voltage applied to the anode formed on the face substrate, and impinge on phosphor layers formed on the face substrate thus exciting the phosphor layers and the light of colors corresponding to lights emitting characteristics of the phosphor layers are generated.

The individual electron source forms a pair with a corresponding phosphor layer so as to constitute a unit pixel. Usually, one pixel (color pixel, pixel) is constituted of the unit pixels of three colors consisting of red (R), green (G) and blue (B). Here, in the case of the color pixel, the unit pixel is also referred to as a sub pixel.

In the planner image display device described above, in general, in the inside of a display region which is arranged between the back substrate and the face substrate and is surrounded by the support body, a plurality of distance holding members (hereinafter referred to as spacers) are arranged and fixed thus holding the distance between the above-mentioned both substrates at a given distance in cooperation with the support body. The spacers are formed of a plate-like body which is made of an insulation material such as glass, ceramics or the like, in general. Usually, the spacers are arranged at positions which do not impede an operation of pixels for every plurality of pixels.

Further, the support body which constitutes the sealing frame is interposed between the back substrate and the face substrate and is fixed to inner peripheries of the back substrate and the face substrate using a sealing material such as frit glass, and the fixing portions are hermetically sealed thus forming sealing regions. The degree of vacuum in the inside of a display region defined by both substrates and the support body is set to 10⁻⁵ to 10⁻⁷ Torr, for example.

First electrode lead terminals which are connected to the first electrodes formed on the back substrate and second electrode lead terminals which are connected to the second electrodes formed on the back substrate penetrate the sealing regions formed between the support body and both substrates. Usually, the support body which constitutes the sealing frame is fixed to the back substrate and the face substrate using the sealing material such as frit glass or the like. The first electrode lead terminals and the second electrode lead terminals are pulled out through the sealing region which constitutes the hermetic sealing portion formed between the sealing frame and the back substrate.

Patent document 3 (Japanese Patent Laid-open publication Hei10(1998)-308189) discloses the constitution in which a static elimination electrode which is normally grounded or is intermittently set to a negative potential within a display operation is arranged in a non-display region around the display region in a state that the static elimination electrode surrounds the non-display region thus preventing flickers of a screen attributed to a discharge or preventing the breakdown of a field emission emitter.

### SUMMARY OF THE INVENTION

In the above-mentioned related art, in the planar image display device, the alignment of electrodes on both substrates is important, wherein particularly with respect to the positional relationship between electron sources on the back substrate side and the phosphor layers on the face substrate side, the alignment of high accuracy in which the displacement of the center of gravities between the electron source and the phosphor layer is restricted to approximately ±10 μm or less is required, for example.

Further, with respect to this type of planar image display device, a technique which simultaneously manufactures a plurality of image display devices by multiple panel formation from a large-sized glass plate and a technique which cuts and separates the large-sized glass plate into individual substrates, aligns the substrates and seals the substrates thus manufacturing the image display devices have been proposed.

Further, in the constitution which performs the sealing of both substrates made of the glass material and the support body which constitutes the sealing frame using the sealing material such as the frit glass as described above, a heating step of approximately 400° C. is indispensable. In such a heating step, the thermal deformation of the glass material is generated as a matter of course and hence, a countermeasure which takes such thermal deformation into consideration is requested. By taking the thermal deformation into consideration, compared to the technique which simultaneously manufactures the plurality of image display devices using the above-mentioned multiple panel formation, the technique which cuts and separates the large-sized glass plate into individual substrates, aligns the substrates and seals the substrates thus manufacturing the image display devices can relatively reduce the thermal deformation.

Further, in the sealing structure which does not request the heating step or allows the heating at a low temperature, the manufacturing technique using the multiple panel formation has characteristics which enable the rationalization of the manufacturing steps and the reduction of the manufacturing cost.

In any one of these techniques, it is apparent that the degree of accuracy of the above-mentioned alignment of electrodes of both substrates is reflected on the degree of excellence of the display characteristics. Although a profile reference method and a method which utilizes positioning marks and the like may be used for such positioning, these methods have advantages and disadvantages respectively. In the profile reference method, there may be a case that it is difficult to set reference points depending on overlapped shapes of both substrates. Further, the positioning mark method has drawbacks including a drawback that mark forming positions are restricted due to the necessity to consider the substrate cutting position, the elimination of a spark generation source in the inside of a vacuum region and the like. A countermeasure to overcome such drawbacks is requested in all of these methods.

Accordingly, the present invention has been made to overcome the above-mentioned drawbacks of the related art and can overcome the drawbacks by arranging non-display island-like electrodes which do not contribute to a display and counter electrodes which face the island-like electrodes in an opposed manner as positioning marks on both substrates within a vacuum region surrounded by both substrates and a support body, and by controlling the island-like electrodes and the counter electrodes at given potentials.

Due to such a constitution, it is possible to ensure the mutual electrode positions between both substrates with high accuracy and, at the same time, it is possible to reduce the generation of sparks by eliminating the island-like electrodes and counter electrodes which constitute the positioning marks from spark generating sources and hence, it is possible to provide an image display device which can perform a desired high quality display and can exhibit a prolonged lifetime.

According to the present invention, by arranging the island-like electrodes which are held at a given potential in a non-display region of one substrate out of both substrates which face each other in an opposed manner, the island-like electrodes in the non-display region do not constitute the spark generating sources and hence, it is possible to obviate the possibility of the generation of sparks whereby an image display device which exhibits a prolonged life time and a high quality display can be obtained.

Further, with respect to both substrates which face each other in an opposed manner, by providing another substrate which allows the recognition of the island-like electrodes through another substrate, it is possible to confirm the counter electrodes and the island-like electrodes from the surface of another substrate through another substrate and hence, it is possible to enhance the positioning accuracy by confirming positions of both electrodes, whereby an image display device which exhibits a high quality display can be obtained.

According to the present invention, since the island-like electrodes are arranged in a spaced apart manner from the electrodes (display region) which contribute to a display, an image display device which exhibits a high quality display can be obtained.

According to the present invention, by arranging the island-like electrodes on the back substrate, the island-like electrodes can be simultaneously formed with other electrodes and hence, the operability is enhanced.

According to the present invention, by connecting the island-like electrodes with the electrodes which contribute to the display, it is possible to control the island-like electrodes at a desired potential and hence, the possibility of generation of sparks can be obviated, whereby an image display device which exhibits a prolonged lifetime and high display quality can be obtained.

According to the present invention, by forming the island-like electrodes using the same material as the electrodes which contribute to a display, it is possible to simultaneously form the island-like electrodes with the electrodes which contribute to the display and hence, the operability can be enhanced and, at the same time, it is possible to obtain the image display device which exhibits a prolonged lifetime and a high quality display.

According to the present invention, by arranging the counter electrodes and island-like electrodes substantially coaxially, the positioning accuracy can be further enhanced and hence, an image display device which exhibits a prolonged lifetime and a high quality display can be obtained.

According to the present invention, by arranging the counter electrodes on the face substrate, the counter electrodes can be easily formed thus enhancing the operability.

According to the present invention, by connecting the counter electrodes with an anode, it is possible to control the counter electrodes at a desired potential and hence, it is possible to obviate the possibility of generation of sparks, whereby an image display device which exhibits a prolonged lifetime and a high quality display can be obtained.

According to the present invention, by forming the counter electrodes and the anode using the same material, it is possible to simultaneously form the counter electrodes and the anode and hence, the operability can be enhanced and, at the same time, an image display device which exhibits a prolonged lifetime and a high quality display can be obtained.

According to the present invention, by making profile sizes of the face substrate and the back substrate different from each other, it is possible to easily ensure a mounting space for a peripheral circuit such as a drive circuit or the like and, at the same time, it is possible to miniaturize an image display device by mounting the peripheral circuit on an end portion of the back substrate.

According to the present invention, by allowing the face substrate and the back substrate to have the same profile size, a material cutting operation for both substrates can be performed in common thus reducing a manufacturing cost.

Further, by overlapping end portions of both substrates in a displaced manner, it is possible to mount the peripheral circuit on the substrate whereby an image display device can be also miniaturized.

According to the present invention, it is possible to use the counter electrodes and the island-like electrodes as positioning marks without using these electrodes as sparks generating sources and hence, it is possible to obtain an image display device which exhibits a prolonged lifetime and a high display quality.

### BRIEF EXPLANATION OF DRAWINGS

FIG. 1A and FIG. 1B are views for explaining one embodiment of an image display device according to the present invention, wherein FIG. 1A is a plan view as viewed from a face substrate side and FIG. 1B is a side view;

FIG. 2 is a schematic plan view of a back substrate by removing a face substrate shown in FIG. 1A;

FIG. 3 is a schematic cross-sectional view along a line A-A in FIG. 1A;

FIG. 4 is a schematic cross-sectional view of the back substrate and a portion of the face substrate which corresponds to the back substrate taken along a line B-B in FIG. 2;

FIG. 5 is an enlarged view of a “C” portion in FIG. 1A;

FIG. 6A and FIG. 6B are views for explaining another embodiment of the image display device of the present invention, wherein FIG. 6A is a plan view as viewed from the face substrate side and FIG. 6B is a side view;

FIG. 7 is a schematic plan view of the back substrate showing still another embodiment of the image display device of the present invention;

FIG. 8 is a schematic plan view of the back substrate showing still another embodiment of the image display device of the present invention;

FIG. 9 is a schematic plan view of the back substrate showing still another embodiment of the image display device of the present invention;

FIG. 10 is a schematic plan view corresponding to FIG. 5 showing still another embodiment of the image display device of the present invention;

FIG. 11 is a schematic perspective view showing still another embodiment of the image display device of the present invention;

FIG. 12A, FIG. 12B and FIG. 12C are views for explaining an example of electron sources which constitute pixels of the image display device of the present invention, wherein FIG. 12A is a plan view, FIG. 12B is a cross-sectional view taken along a line E-E in FIG. 12A, and FIG. 12C is a cross-sectional view taken along a line F-F in FIG. 12A; and

FIG. 13 is an explanatory view of an equivalent circuit example of the image display device to which the constitution of the present invention is applied.

### DESCRIPTION OF THE PREFERRED EMBODIMENTS

Hereinafter, embodiments of the present invention are explained in detail in conjunction with drawings showing the embodiments. Here, although the explanation will be made with respect to a case in which the present invention is applied to an electron emission FPD, the present invention is similarly applicable to other substantially equal display devices or similar apparatuses.

### Embodiment 1

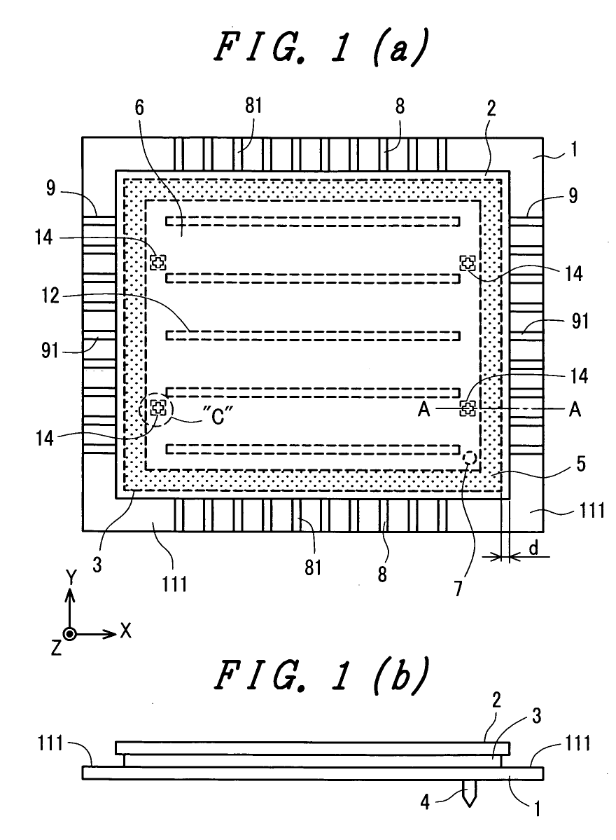

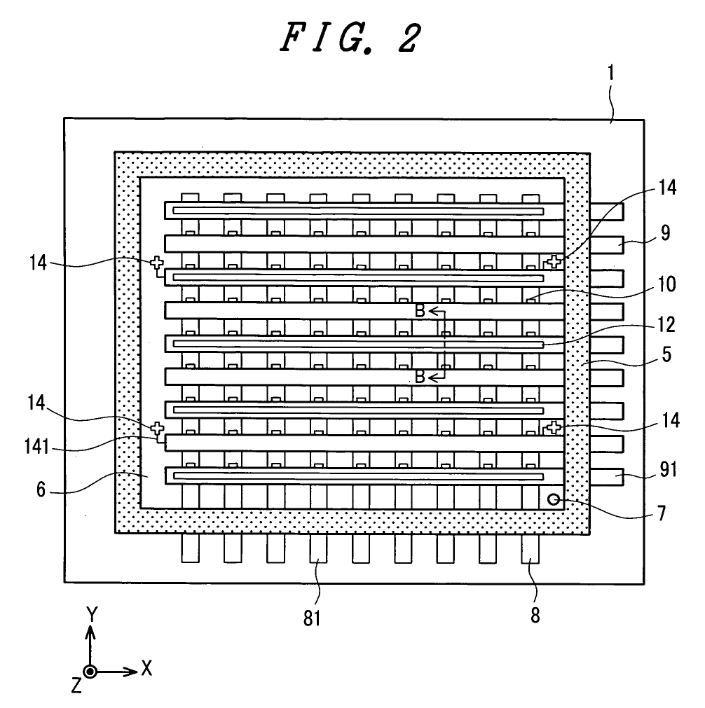

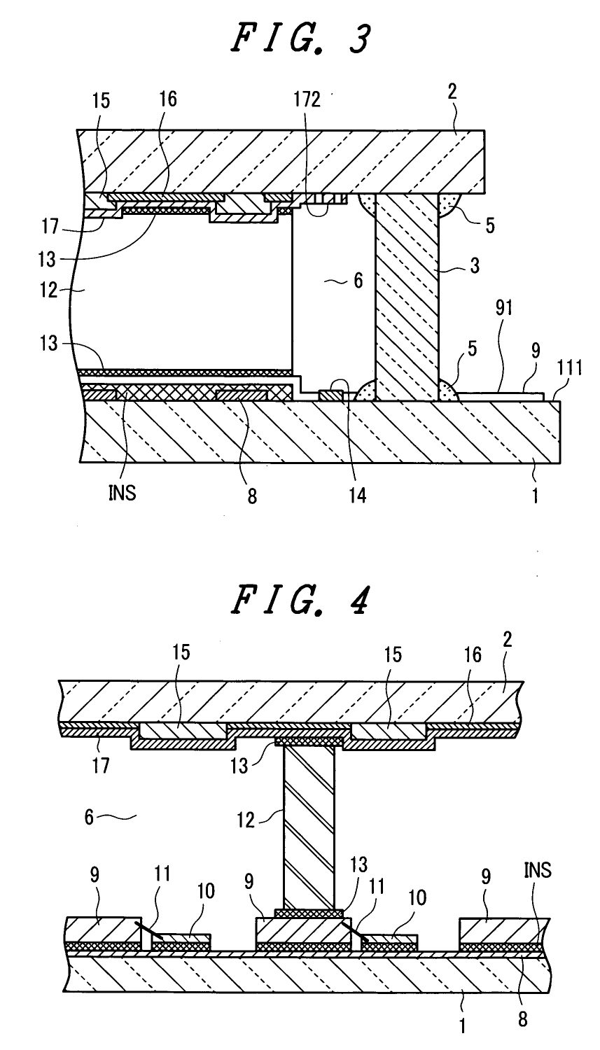

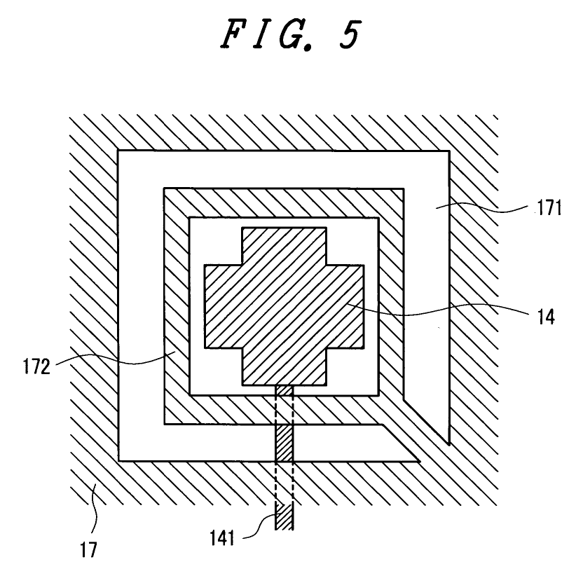

FIG. 1A to FIG. 5 are views for explaining one embodiment of an image display device according to the present invention, wherein FIG. 1A is a plan view as viewed from a face substrate side, FIG. 1B is a side view, FIG. 2 is a schematic plan view of a back substrate by removing a face substrate shown in FIG. 1A, FIG. 3 is a schematic cross-sectional view along a line A-A in FIG. 1A, FIG. 4 is a schematic cross-sectional view of a back substrate along a line B-B in FIG. 2 and a schematic cross-sectional view of the portion of a face substrate corresponding to the back substrate, and FIG. 5 is an enlarged view of a “C” portion shown in FIG. 1A.

In these FIG. 1A to FIG. 5, numeral 1 indicates a back substrate and numeral 2 indicates a face substrate, wherein both substrates 1, 2 are formed of a glass plate having a thickness of several mm, for example, approximately 3 mm. A profile size of the back substrate 1 is set larger than a profile size of the face substrate 2. Numeral 3 indicates a support body which is formed of a glass plate or a sintered body made of frit glass having a thickness of several mm, for example, approximately 3 mm. Numeral 4 indicates an exhaust pipe which is fixedly secured to the back substrate 1. The support body 3 is inserted between both substrates 1, 2 in a state that the support body 3 surrounds peripheral portions of the substrates 1, 2 and the both substrates 1, 2 are hermetically sealed to the support body 2 using a sealing material 5 such as frit glass. The substrates 1, 2 are arranged coaxially in the overlapping direction (Z direction) and the back substrate 1 has non-overlapped portions 111 outside the face substrate 2. The face substrate 2 projects outwardly from the support body 3 in the X direction or in the Y direction by a size d which is equal to or less than 1 mm.

Alternatively, in place of allowing the face substrate 2 to project to the outside from the support body 3, it is possible to allow the face substrate 2 to retract inwardly from the support body 3, wherein a retraction size is equal to or less than 1 mm.

A space which is surrounded by the support body 3, both substrates 1, 2 and the sealing material 5 is evacuated through the above-mentioned exhaust pipe 4 thus constituting a display region 6 holding a degree of vacuum of, for example, 10⁻³ to 10⁻⁷ Pa. Further, the exhaust pipe 4 is mounted on an outer surface of the back substrate 1 as mentioned previously and is communicated with a through hole 7 which is formed in the back substrate 1 in a penetrating manner. After completing the evacuation, the exhaust pipe 4 is sealed.

Numeral 8 indicates video signal electrodes and these video signal electrodes 8 extend in one direction (Y direction) and are arranged in parallel in another direction (X direction) on an inner surface of the back substrate 1. These video signal electrodes 8 have video signal electrode lead terminals 81 at end portions thereof. The distal end portions of these terminals 81 hermetically penetrate the hermetically-sealed portions between the support body 3 and the back substrate 1 and, thereafter, extend to the non-overlapped portions 111 of the end potion disposed more outside than the end surface of the face substrate 2. Accordingly, in the non-overlapped portions 111 formed on the end portions of the back substrate 1 disposed more outside than end surfaces of the face substrate 2, the video signal electrode lead terminals 81 assume an exposed state.

Next, numeral 9 indicates scanning signal electrodes. The scanning signal electrodes 9 extend over the video signal electrodes 8 in another direction (X direction) which intersect the video signal electrodes 8 and are arranged in parallel in one direction (Y direction). These scanning signal electrodes 9 have scanning signal electrode lead terminals 91 at end portions thereof. Distal end portions of the terminals 91 hermetically penetrate hermetically-sealed portions between the support body 3 and the back substrate 1 and, thereafter, extend to the non-overlapped portions 111 of the end potions disposed more outside than the end surfaces of the face substrate 2. Accordingly, in the non-overlapped portion 111 of the end portions of the back substrate 1 disposed more outside than the end surfaces of the face substrate 2, the scanning signal electrode lead terminals 91 assume an exposed state.

Next, numeral 10 indicates electron sources, wherein the electron sources 10 are formed in the vicinity of respective intersecting portions of the scanning signal electrodes 9 and the video signal electrodes 8, and the electron sources 10 and the scanning signal electrodes 9 are connected with each other by connection electrodes 11. Further, an interlayer insulation film INS is arranged between the video signal electrodes 8 and the scanning signal electrodes 9.

Here, the video signal electrodes 8 are formed of an Al/Nd film, for example, while the scanning signal electrodes 9 are formed of an Ir/Pt/Au film or the like, for example.

Next, numeral 12 indicates spacers, wherein the spacers 12 are made of a ceramic material and are shaped in a rectangular thin plate shape. In this embodiment, the spacers 12 are arranged upright above the scanning signal electrodes 9 every other line, and are fixed to both substrates 1, 2 using an adhesive material 13. The spacers 12 are usually arranged at positions which do not impede operations of pixels for every plurality of respective pixels.

Sizes of the spacers 12 are set based on sizes of substrates, a height of the support body 3, materials of the substrates, an arrangement interval of the spacers 12, a material of spacers and the like. However, in general, the height of the spacers 12 is approximately equal to a height of the support body 3. A thickness of the spacers 12 is set to several 10 μm or more to several mm or less, while a length of the spacers 12 is set to approximately 20 mm to 200 mm. Preferably, a practical value of the length of the spacers 12 is approximately 80 mm to 120 mm. Further, the spacers 12 possess a resistance value of approximately 10⁸ to 10⁹ Ω·cm.

Next, numeral 14 indicates cruciform island-like electrodes. A plurality of island-like electrodes 14 are arranged within the display region 6 at positions in the vicinity of the support body 3 where the island-like electrodes 14 do not obstruct a normal display and are connected to the scanning signal electrodes 9 through lead lines 141. The island-like electrodes 14 and the lead lines 141 can be formed simultaneously as the time of forming the scanning signal electrodes 9 using the same material. Further, the island-like electrodes 14 are configured such that the island-like electrodes 14 can be recognized from on outer surface of the face substrate 2.

On an inner surface of the face substrate 2 at the back substrate 1 side, phosphor layers 15 of red, green and blue are arranged in a state that these phosphor layers 15 are defined by a light-shielding BM (black matrix) film 16. A metal back (an anode electrode) 17 made of a metal thin film is formed in a state that the metal back 17 covers the phosphor layers 15 and the BM film 16 by a vapor deposition method, for example, thus forming a phosphor screen. A window portion 171 is formed in the metal back 17 at a position where the metal back 17 faces the island-like electrode 14. A frame-like counter electrode 172 having a shape and a size which allow the counter electrode 172 to surround the island-like electrode 14 is arranged on the window portion 171. Such a constitution allows the recognition of the island-like electrodes 14 including the counter electrodes 172 from the outer surface of the face substrate 2.

Further, with respect to a phosphor material of these phosphor layers 15, for example, Y₂O₂S:Eu(P22-R) is used as the red phosphor, ZnS:Cu,Al(P22-G) is used as the green phosphor, and ZnS:Ag,Cl (P22-B) is used as the blue phosphor. With such phosphor screen constitution, electrons irradiated from the above-mentioned electron source 10 are accelerated and impinge on the phosphor layers 15 which constitute the corresponding pixels. Accordingly, the phosphor layer 15 emits light of the given color and the light is mixed with an emitted light of color of the phosphor of another pixel thus constituting the color pixel of a given color. Further, although the anode electrode 17 is indicated as a face electrode, the anode electrodes 17 can be formed of stripe-like electrodes which are divided for every pixel column while intersecting the scanning signal electrodes 9.

According to the constitution of the embodiment 1, by aligning the plurality of island-like electrodes 14 on the back substrate 1 and the plurality of counter electrodes 172 on the face substrate 2 side which is arranged to face the back substrate 1 respectively, it is possible to enhance the positioning accuracy of both substrates and hence, the image display device which exhibits the high quality display can be obtained. Further, the given voltages are applied to the island-like electrodes 14 and the counter electrodes 172 respectively and hence, potential floating spots which constitute spark generating sources are not present, whereby the generation of spark can be suppressed and the image display device which exhibits the prolonged lifetime and high reliability can be obtained. Further, by adopting the constitution which makes profile sizes of both substrates 1, 2 different from each other thus forming non-overlapped portions 111 on respective end portions of the back substrate 1, the mounting of a peripheral circuit is facilitated thus enhancing the operability and, at the same time, miniaturizing an image display device.

### Embodiment 2

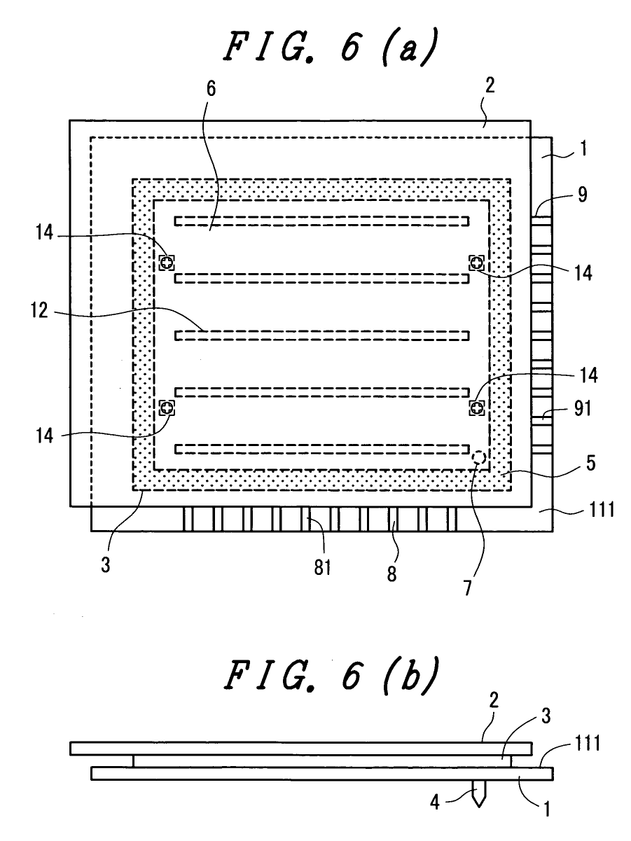

FIG. 6A and FIG. 6B show another embodiment of the image display device and correspond to FIG. 1A and FIG. 1B respectively, wherein parts identical with the parts in the above-mentioned drawings are given the same symbols. In FIG. 6A and FIG. 6B, a back substrate 1 and a face substrate 2 have the same profile size, wherein both substrates 1, 2 are overlapped in a state that the centers of gravity are displaced so that non-overlapped portions 111 are formed on only two sides of the back substrate 1. Further, respective video signal electrode lead terminals 81 and scanning signal electrode lead terminals 91 of video signal electrodes 8 and scanning signal electrodes 9 are pulled out to only the non-overlapped portion 111 sides.

According to the constitution of the embodiment 2, by allowing both substrates 1, 2 to have the same profile size, the management of parts can be facilitated and the parts can be manufactured at a low cost. Further, by adopting the constitution which pulls out the electrode lead terminals 81, 91 to the non-overlapped portions 111, a peripheral circuit can be easily mounted thus enabling the miniaturization of the image display device.

### Embodiment 3

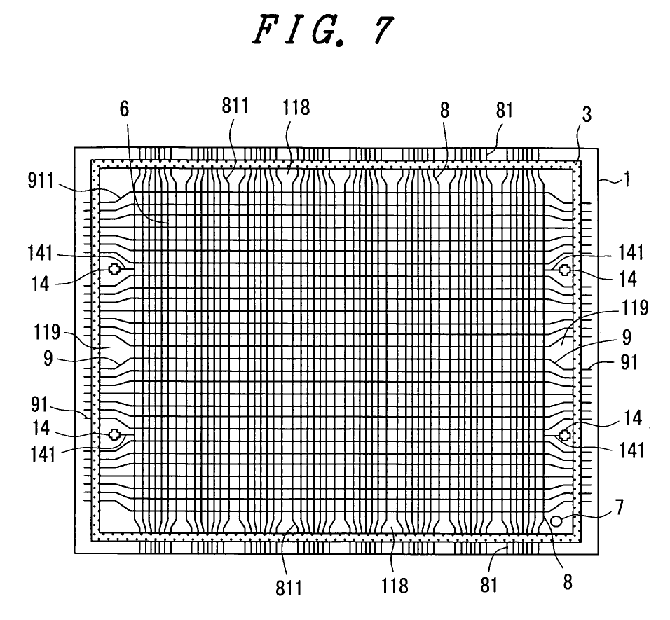

FIG. 7 is a schematic plan view showing a back substrate of still another embodiment of the image display device according to the present invention in a state that a face substrate is removed. Parts identical with the parts in the above-mentioned drawings are given the same symbols. In FIG. 7, video signal electrode lead terminals 81 and scanning signal electrode lead terminals 91 respectively include folded portions 811, 911 at positions close to a support body 3 in the inside of a display region 6 corresponding to the connection with peripheral circuit elements not shown in the drawing. Since an inter-terminal pitch inside the peripheral circuit element is set smaller than an electrode pitch, the bending direction of the folded portions 811, 911 is directed in the center direction of the peripheral circuit element. Due to such a constitution, between the wirings of neighboring peripheral circuit elements, inter-wiring exposure regions 118, 119 having an area wider than a region between electrode lead terminals in the inside of one peripheral circuit element are formed. Then, a plurality of island-like electrodes 14 are arranged in the inter-wiring exposure regions 119 and, at the same time, the islands 14 are connected with the video signal electrodes 8 through the lead lines 141. Although not shown in the drawing, it is needless to say that counter electrodes which face the island-like electrodes 14 in an opposed manner are arranged on the face substrate 2.

According to the constitution of the embodiment 3, by arranging the island-like electrodes 14 in an inter-wiring exposure regions 119 having a larger area than the above-mentioned area between the electrode lead terminals and by connecting the island-like electrodes 14 to the video signal electrodes 8, potential floating spots which constitute spark generating sources do not exist and hence, the spark generation can be suppressed whereby it is possible to obtain the image display device which exhibits a prolonged lifetime and high reliability.

### Embodiment 4

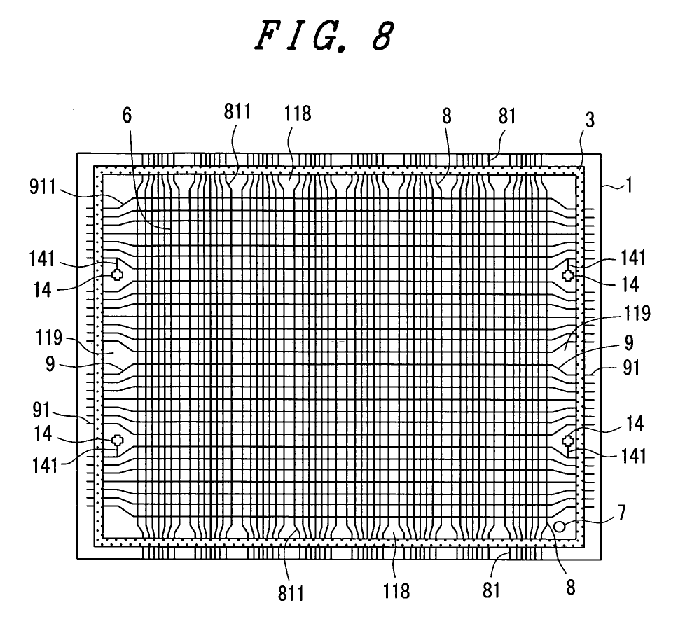

FIG. 8 is a schematic plan view showing a back substrate of still another embodiment of the image display device according to the present invention in a state that a face substrate is removed. Parts identical with the parts in the above-mentioned drawings are given the same symbols. In this embodiment 4, island-like electrodes 14 are connected with scanning signal electrodes 9 through the lead lines 141 and other constitutions are equal to the corresponding constitutions of the embodiment 3. Due to the constitution of the embodiment 4, it is possible to obtain the manner of operation and advantageous effects similar to the manner of operation and advantageous effects of the embodiment 3.

### Embodiment 5

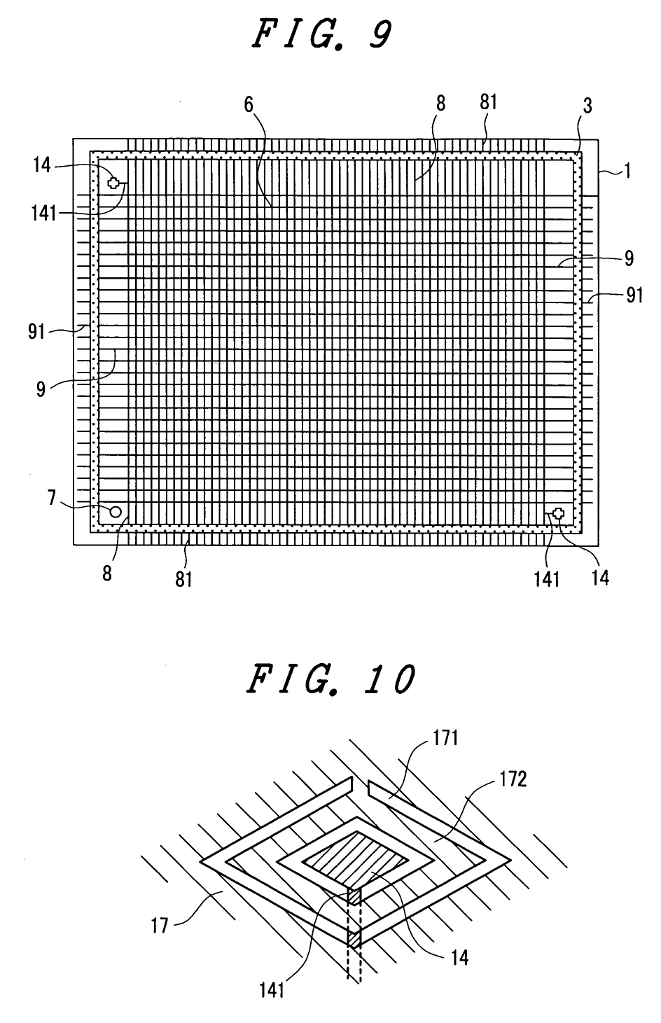

FIG. 9 is a schematic plan view showing a back substrate of still another embodiment of the image display device according to the present invention in a state that a face substrate is removed. Parts identical with the parts in the above-mentioned drawings are given the same symbols. In this embodiment 5, island-like electrodes 14 are arranged in exposure regions at corner portions different from a corner portion where an exhaust hole 7 of a corner portion of a display region 6 is formed in an opposed manner in the orthogonal direction, and the island-like electrodes 14 are respectively connected with video signal electrodes 8 through lead lines 141.

According to the constitution of the embodiment 5, by connecting the island-like electrodes 14 to the video signal electrodes 8, potential floating spots which constitute spark generating sources do not exist and hence, the spark generation can be suppressed whereby it is possible to obtain the image display device which exhibits a prolonged lifetime and high reliability.

Further, an exposure region in a corner portion is a region which can easily ensure a relatively large area and affects the display slightly. Accordingly, a size of the island-like electrode can be enlarged and hence, the accuracy of the positioning can be enhanced whereby it is possible to obtain the image display device capable of performing a high quality display.

Further, by applying a given voltage to the island-like electrode 14, potential floating spots which constitute spark generating sources do not exist and hence, the spark generation can be suppressed whereby it is possible to obtain the image display device which exhibits a prolonged lifetime and high reliability. Further, according to the constitution of the embodiment 5, it is possible to perform the positioning at three points consisting of two island-like electrodes 14 which are arranged in an opposed manner in the orthogonal direction of a display area 6 and an exhaust through hole 7 formed in an exposure region of another corner portion.

### Embodiment 6

FIG. 10 is a schematic plan view showing still another embodiment of the image display device according to the present invention and corresponds to FIG. 5. Parts identical with the parts in the above-mentioned drawings are given the same symbols. In FIG. 10, an island-like electrode 14 has a diamond shape and is connected with a given power source through a lead line 141. On the other hand, a window portion 171 of an anode 17 which corresponds to the island-like electrode 14 also has a diamond shape, and an inner center portion is removed in a diamond shape having an area larger than the island-like electrode 14 thus forming a counter electrode 172.

Due to the constitution of the embodiment 6, it is possible to perform the positioning of respective corner portions of the diamond shape more accurately and hence, the positioning accuracy can be enhanced whereby it is possible to obtain an image display device which can perform a high quality display.

### Embodiment 7

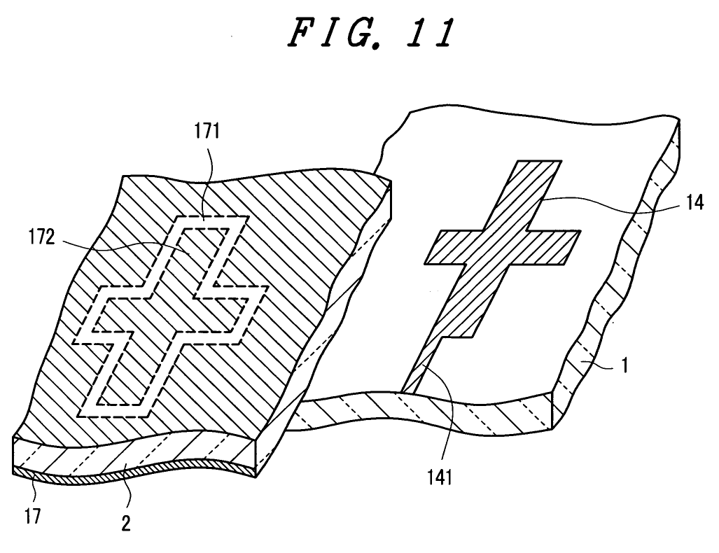

FIG. 11 is a schematic perspective view showing still another embodiment of the image display device according to the present invention and parts identical with the parts in the above-mentioned drawings are given the same symbols. In the embodiment 7, island-like electrodes 14 and counter electrodes 172 are formed in shapes congruent or similar to each other. The combination of the island-like electrode 14 and the counter electrode 172 is arranged in the same manner as the above-mentioned respective embodiments.

Due to the constitution of the embodiment 7, the island-like electrode 14 and the counter electrode 172 have the substantially equal shape and hence, it is possible to perform the positioning more accurately and hence, the positioning accuracy can be enhanced whereby it is possible to obtain the image display device which can perform a high quality display.

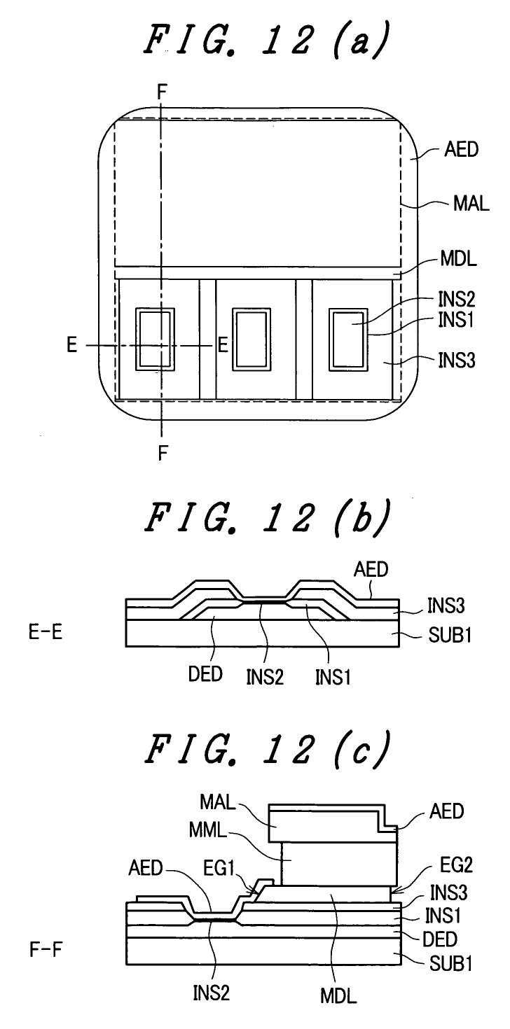

FIG. 12A, FIG. 12B and FIG. 12C are views for explaining an example of electron sources which constitutes pixels of the image display device of the present invention, wherein FIG. 12A is a plan view, FIG. 12B is a cross-sectional view taken along a line E-E in FIG. 12A, and FIG. 12C is a cross-sectional view taken along a line F-F in FIG. 12A. The electrons sources are formed of an MIM type electron source.

Next, the structure of the electron source is explained in conjunction with manufacturing steps. First of all, on the back substrate SUB1, lower electrodes DED (the video signal electrodes 8 in the above-mentioned respective embodiments), a protective insulation layer INS1, an insulation layer INS2 are formed. Next, an interlayer film INS3, upper bus electrodes (the scanning signal electrodes 9 in the above-mentioned respective embodiments) which become electricity supply lines to upper electrodes AED, and a metal film which constitutes a spacer electrode for arranging spacers 12 are formed by a sputtering method, for example. Although the lower electrodes and the upper electrodes are made of aluminum, these electrodes are made of other metal described later.

The interlayer film INS3 may be made of silicon oxide, silicon nitride, silicon or the like, for example. Here, the interlayer film INS3 is made of silicon nitride and has a film thickness of 100 nm. The interlayer film INS3, when a pin hole is formed in a protective insulation layer INS1 formed by anodizing, fills a void and plays a role of ensuring the insulation between a lower electrode DED and an upper bus electrode (a three-layered laminated film which sandwiches copper (Cu) which constitutes a metal film intermediate layer MML between a metal film lower layer MDL and a metal film upper layer MAL).

Here, the upper bus electrode is not limited to the above-mentioned three-layer laminated film and the number of layers may be increased more. For example, the metal film lower layer MDL and the metal film upper layer MAL may be made of a metal material having high oxidation resistance such as aluminum (Al), chromium (Cr), tungsten (W), molybdenum (Mo) or the like, an alloy containing such metal, or a laminated film of these metals. Here, the metal film lower layer MDL and the metal film upper layer MAL are made of an alloy of aluminum and neodymium (Al—Nd). Besides the alloy, with the use of a five-layered film in which the metal film lower layer MDL is a laminated film formed of an Al alloy and Cr, W, MO or the like, the metal film upper layer MAL is a laminated film formed of Cr, W, Mo or the like and an Al alloy, and films which are brought into contact with the metal film intermediate layer MML made of Cu are made of a high-melting-point metal, in a heating step of a manufacturing process of the image display device, the high-melting-point metal functions as a barrier film thus preventing Al and Cu from being alloyed whereby the five-layered film is particularly effective in the reduction of resistance of wiring.

When the metal film lower layer MDL and the metal film upper layer MAL are made of only Al—Nd alloy, a film thickness of the Al—Nd alloy in the metal film upper layer MAL is larger than a film thickness of the Al—Nd alloy in the metal film lower layer MDL, and a thickness of Cu of the metal film intermediate layer MML is made as large as possible to reduce the wiring resistance. Here, the film thickness of the metal film lower layer MDL is 300 nm, the film thickness of the metal film intermediate layer MML is 4 μm, and the film thickness of the metal film upper layer MAL is 450 nm. Here, Cu in the metal film intermediate layer MML can be formed by electrolytic plating or the like besides sputtering.

With respect to the above-mentioned five-layered film which uses high-melting-point metal, in the same manner as Cu, it is particularly effective to use a laminated film which sandwiches Cu with Mo which can be etched by wet etching in a mixed aqueous solution of phosphoric acid, acetic acid and nitric acid as the metal film intermediate layer MML. In this case, a film thickness of Mo which sandwiches Cu is set to 50 nm, a film thickness of the Al alloy of the metal film lower layer MDL which sandwiches the metal film intermediate layer MML together with the metal film upper layer MAL is 300 nm, and the film thickness of the Al alloy of the metal film upper layer MAL which sandwiches the metal film intermediate layer MML together with the metal film lower layer MDL is 450 nm.

Subsequently, the metal film upper layer MAL is formed in a stripe shape which intersects the lower electrode DED by performing the patterning of resist by screen printing and etching. In performing the etching, for example, a mixed aqueous solution of phosphoric acid and acetic acid is used for wet etching. By excluding the nitric acid from the etchant, it is possible to selectively etch only the Al—Nd alloy without etching Cu.

Also in case of the five-layered film which uses Mo, by excluding the nitric acid from the etchant, it is possible to selectively etch only the Al—Nd alloy without etching Mo and Cu. Here, although one metal film upper layer MAL is formed per one pixel, two metal film upper layer MAL is formed per one pixel.

Subsequently, by using the same resist film directly or using the Al—Nd alloy of the metal film upper layer MAL as a mask, Cu of the metal film intermediate layer MML is etched by wet etching using a mixed aqueous solution of phosphoric acid, acetic acid and nitric acid. Since an etching speed of Cu in the etchant made of mixed aqueous solution of phosphoric acid, acetic acid and nitric acid is sufficiently fast compared to an etching speed of the Al—Nd alloy and hence, it is possible to selectively etch only Cu of the metal film intermediate layer MML. Also in case of the five-layered film which uses Mo, the etching speeds of Mo and Cu are sufficiently fast compared to an etching speed of the Al—Nd alloy and hence, it is possible to selectively etch only the three-layered film made of Mo and Cu. In etching Cu, besides the above-mentioned aqueous solution, an ammonium persulfate aqueous solution, a sodium persulfate can be effectively used.

Subsequently, the metal film lower layer MDL is formed in a stripe shape which intersects the lower electrode DED by performing the patterning of resist by screen printing and etching. The etching is performed by wet etching using a mixed aqueous solution of phosphoric acid and acetic acid. Here, by displacing the printing resist film from the position of the stripe electrode of the metal film upper layer MAL, one-side end portion EG1 of the metal film lower layer MDL projects from the metal film upper layer MAL thus forming a contact portion to ensure the connection with the upper electrode AED in a later stage. Further, on another side end portion EG2 of the metal film lower layer MDL opposite to the above-mentioned one-side end portion EG1, using the metal film upper layer MAL and the metal film intermediate layer MML as masks, the over-etching is performed and hence, a retracting portion is formed on the metal film intermediate layer MML as if eaves are formed.

Due to the eaves of the metal film intermediate layer MML, the upper electrode AED which is formed as a film in a later step is separated. Here, since the film thickness of the metal film upper layer MAL is set larger than the film thickness of the metal film lower layer MDL and hence, even when the etching of the metal film lower layer MDL is finished, it is possible to allow the metal film upper layer MAL to remain on Cu of the metal film intermediate layer MML. Due to such a constitution, it is possible to protect a surface of Cu with the metal film upper layer MAL and hence, it is possible to ensure the oxidation resistance even when Cu is used. Further, it is possible to separate the upper electrode AED in a self-aligning manner and it is possible to form the upper bus electrodes which constitute scanning signal lines which perform the supply of electricity. Further, in case that the metal film intermediate layer MML is formed of the five-layered film which sandwiches Cu with Mo, even when the Al alloy of the metal film upper layer MAL is thin, Mo suppresses the oxidation of Cu and hence, it is not always necessary to make the film thickness of the metal film upper layer MAL larger than the film thickness of the metal film lower layer MDL.

Subsequently, electron emission portions are formed as openings in the interlayer film INS3. The electron emission portion is formed in a portion of an intersecting portion of a space which is sandwiched by one lower electrode DED inside the pixel and two upper bus electrodes (a laminated film consisting of metal film lower layer MDL, metal film intermediate layer MML, metal film upper layer MAL) which intersect the lower electrode DED and a laminated film consisting of metal film lower layer MDL, metal film intermediate layer MML, metal film upper layer MAL of neighboring pixel not shown in the drawing). The etching is performed by dry etching which uses an etching gas containing CF₄ and SF₆ as main components, for example.

Finally, the upper electrode AED is formed as a film. The upper electrode AED is formed by a sputtering method. The upper electrode AED may be made of aluminum or a laminated film made of iridium (Ir), platinum (Pt) and Au (gold), wherein a film thickness may be 6 nm, for example. Here, the upper electrode AED is, at one end portion (right side in FIG. 12C) of an upper bus electrode (a laminated film consisting of a metal film lower layer MDL, a metal film intermediate layer MML and a metal film upper layer MAL), cut by a retracting portion (EG2) of the metal film lower layer MDL formed by the eaves structure of the metal film intermediate layer MML and the metal film upper layer MAL. Then, at another end portion (left side in FIG. 12C) of the upper bus electrode, the upper electrode AED is formed and is connected with the upper bus electrode (the laminated film consisting of the metal film lower layer MDL, the metal film intermediate layer MML and the metal film upper layer MAL) by a contact portion (EG1) of the metal film lower layer MDL without causing a disconnection thus providing the structure which supplies electricity to the electron emission portions.

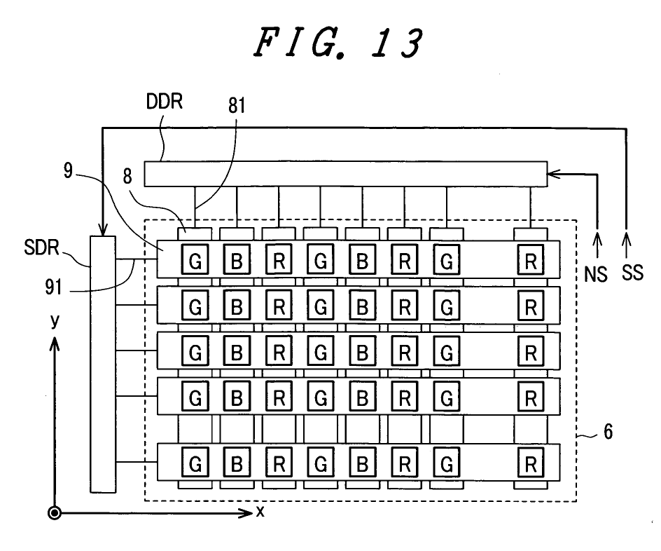

FIG. 13 is an explanatory view of an example of an equivalent circuit of an image display device to which the constitution of the present invention is applied. A region depicted by a broken line in FIG. 13 indicates a display region 6. In the display region 6, n pieces of video signal electrodes 8 and m pieces of scanning signal electrodes 9 are arranged in a state that these electrodes intersect each other thus forming pixels which are arranged in a matrix array of n×m. Sub pixels are formed over the respective intersecting portions of the matrix and one group consisting of three unit pixels (or sub pixels) “R”, “G”, “B” in the drawing constitutes one color pixel. Here, the constitution of the electron sources is omitted from the drawing. The video signal electrodes (cathode electrodes) 8 are connected to the video signal drive circuit DDR through the video signal electrode lead terminals 81, while the scanning signal electrodes (gate electrodes) 9 are connected to the scanning signal drive circuit SDR through the scanning signal electrode lead terminal 91. The video signal NS is inputted to the video signal drive circuit DDR from an external signal source, while the scanning signal SS is inputted to the scanning signal drive circuit SDR in the same manner.

Due to such a constitution, by supplying the video signal to the video signal electrodes 8 which intersect the scanning signal electrodes 9 which are sequentially selected, it is possible to perform a two-dimensional full color image. With the use of the display panel having this constitution, it is possible to realize the image display device at a relatively low voltage with high efficiency.

What is claimed is:

1. An image display device comprising:
a back substrate which includes a plurality of first electrodes which extend in the first direction and are arranged in parallel in the second direction which intersects the first direction, an insulation film which is formed in a state that the insulation film covers the first electrodes, a plurality of second electrodes which extend in the second direction and are arranged in parallel in the first direction over the insulation film, and electrons which are provided in the vicinity of intersecting portions of the first electrodes and the second electrodes;
a face substrate which includes phosphor layers of plurality of colors which emit light due to excitation thereof by electrons taken out from the electron sources of the back substrate and a third electrode, the face substrate facing the back substrate with a given distance therebetween;
a support body which is interposed between the back substrate and the face substrate in a state that the support body surrounds a display region and holds the given distance;
a sealing material which hermetically seals end surfaces of the support body and the face substrate and the back substrate respectively;
first electrode lead terminals which have at least one ends of the first electrodes pulled out to the outside from the display region through a hermetic sealing region where the back substrate and the support body face each other in an opposed manner; and
second electrode lead terminals which have at least one ends of the second electrodes pulled out to the outside from the display region through a hermetic sealing region where the back substrate and the support body face each other in an opposed manner; wherein
the back substrate and the face substrate are overlapped to each other in a state that a portion of the back substrate projects from the face substrate, and the end surfaces of the support body and the face substrate and the back substrate are respectively hermetically sealed, and
either one of the back substrate and the face substrate includes a plurality of island-like electrodes which are held at a given potential on an inner surface thereof which faces another substrate, and another substrate includes counter electrodes which allow the recognition of the island-like electrodes through another substrate.

2. An image display device according to claim 1, wherein the island-like electrodes are arranged at positions inside the sealing region and close to the support body.

3. An image display device according to claim 1, wherein the island-like electrodes are arranged on the back substrate.

4. An image display device according to claim 3, wherein the island-like electrodes are connected with the first electrodes or the second electrodes.

5. An image display device according to claim 3, wherein the island-like electrodes are connected with a power source different from the first electrodes and the second electrodes through lead lines.

6. An image display device according to claim 4, wherein the island-like electrodes are made of the same material as the first electrodes or the second electrodes.

7. An image display device according to claim 1, wherein the counter electrodes are arranged at positions substantially coaxial with the island-like electrodes in the overlapping direction of both substrates.

8. An image display device according to claim 1, wherein the counter electrodes are arranged on the face substrate.

9. An image display device according to claim 8, wherein the counter electrode is connected to the third electrode.

10. An image display device according to claim 8, wherein the counter electrodes are formed of the same material as the third electrodes.

11. An image display device according to claim 1, wherein the face substrate and the back substrate differ from each other in a profile size.

12. An image display device according to claim 1, wherein the face substrate and the back substrate have the same profile size.

13. An image display device according to claim 1, wherein the first electrodes constitute video signal electrodes, the second electrode constitute scanning signal electrodes, and the third electrode constitutes an anode electrode.
